(19) United States
(12) Patent Application Publication
(10) Pub. No.: US 2021/0072338 A1
(43) Pub. Date: Mar. 11, 2021

(54) INTERFEROMETRIC LIGHTNING DETECTION SYSTEM

(71) Applicant: SELERYS, Rousset (FR)

(72) Inventors: Philippe CARDI, Rousset (FR); Jean-Yves LOJOU, Marseille (FR)

(73) Assignee: SELERYS, Rousset (FR)

(21) Appl. No.: 16/955,987

(22) PCT Filed: Dec. 20, 2018
(86) PCT No.: PCT/FR2018/053482

§ 371 Date: Jun. 19, 2020

(30) Foreign Application Priority Data
Dec. 20, 2017 (FR) 1762580

(51) Int. Cl. G01S 3/48; G01R 29/08; H01Q 19/10; H01Q 21/20; H01Q 5/307

(52) U.S. Cl. CPC G01S 3/48; G01R 29/0842; H01Q 5/307; H01Q 21/205; H01Q 19/108

(57) ABSTRACT

The invention relates to a system for interferometrically detecting an electromagnetic source, having two antenna modules, each antenna module comprising two conductive elements, one planar reflector having a first face and a second face, the first faces of the planar reflectors of the antenna modules engaging respectively and integrally with the two conductive elements of the antenna modules, the two antenna modules being mutually arranged so that the second faces of the planar reflectors thereof form a projecting angle.

The invention relates to the field of devices or systems applied with the detection and/or observation of electromagnetic sources. Such devices or systems are used for all types of usage, and preferably, but non-limitingly, in connection with meteorological phenomena, and more specifically to perform lightning detection functions.

In the remainder of the document, the invention will be described preferably, but non-limitingly, in the context of lightning prevention, that is to say, in the context of actions aiming to reduce or avoid any damage that may be caused by thunderstorms, more specifically, lightning phenomena in territories that are more or less sensitive than others, such as agricultural areas, or on infrastructure, for example.

Within the meaning of the invention and throughout the entire document, for simplification purposes, the terms “flash(es)” and “lightning” will be used interchangeably.

For decades, lightning has fascinated humans, more specifically scientists. Lightning has also been the subject of many studies in the meteorology field, since it presents many dangers, which may cause colossal damage, both in terms of goods and people, for example triggering fires, possible electrocution of humans and/or animals that may potentially cause death, electromagnetic interference that may be harmful to communication, aviation and/or navigation, destruction of electronic components in infrastructure and/or equipment.

During a thunderstorm, two phenomena are commonly observed: one or several flashes consisting of one or several electrical discharges causing an electromagnetic wave, visible results of the heating of the air, and thunder corresponding to a noise emitted during the sudden expansion of the air heated up during the passage of this current. Indeed, lightning consists of a natural discontinuous electrostatic discharge phenomenon, such a phenomenon generally occurring in thunderstorm cloud regions charged with static electricity, that is to say either in or between such clouds (Cloud lightning), or between such clouds and the air or the ground (Cloud to Ground (CG) lightning), the ground being able to comprise one or several land or maritime zones. Irrespective of the nature of the flash, it is preceded and followed by electrical phenomena of lower intensity respectively called “leaders” and “streamers.” Generally, the leaders determine the path of the flashes. There are two major families of leaders: stepped leaders or leader strokes, which precede the first arc of the cloud to ground flash and which progress toward the ground by leaps approximately fifty meters long, and dart leaders, which precede the subsequent arcs of the cloud to ground flashes as well as the different types of intra-cloud flashes. The systems capable of detecting both the flashes and the leaders and streamers are called “total lightning” detection. They generally operate at high frequency (VHF-UHF), in which bands the radiation of these phenomena is the most intense. The appearance of the lightning causes the creation of a plasma, that is to say, a medium made up of a mixture of neutral particles, positive ions and negative electrons, produced in the air over the journey of the discharge, causing the appearance of two previously mentioned phenomena: on the one hand, the flash, which propagates very quickly, and on the other hand, thunder, which results from an explosive expansion of the air heated by the flash, and which propagates relatively slowly, in particular compared with the flash. Generally, the lightning tends to hit the ground close to the generating cloud, in particular in high-altitude regions, and/or more specifically buildings, trees, or any protruding objects on the ground or sea. The thunder, in turn, may resonate with a noise, such as a dry and immediate cracking, when the flash is close, or alternatively, rumble more broadly in the distance, more specifically when the thunderstorm is occurring in a mountainous region, particularly due to echo effects. Since light propagates more quickly in the air than sound, the flash is generally visible well before the thunder is audible, thus making it possible to approximate the distance at which the lightning has “struck.”

The thunderclouds develop from cumulonimbi or groups of cumulonimbi, also described as “thunderclouds,” such cumulonimbi being able to contain a hundred thousand tons of water, hail and small ice crystals. Said cumulonimbi are generally subject to speed shear, that is to say, variations in the wind speed as a function of the altitude, directional shear, that is to say, variations in the direction of the wind as a function of the altitude, and intense updrafts and subsidence. This turbulence is the source of impacts between the particles making up the cloud, in particular the ice crystals and the water droplets. The redundancy of these collisions causes the electrons to be pulled away from the particles and thus causes charges to appear. The heaviest particles house the negative charges, while the lighter ones, supported by the rising currents, are positively charged. Inside the cumulonimbus or cumulonimbi, a complex electrification process then causes the separation of positive and negative electrostatic charges, and therefore the creation of an intense electrical field.

Once this field reaches a sufficient value, an ionized channel then forms, also described as a descending leader, corresponding to the flash and propagating by successive leaps from the cloud toward the ground.

The physical processes at the origin of thunderstorms are complex and in particular involve many unforeseeable elements, since they are subject to constant change. Aside from the state of the atmosphere, the formation of thunderstorms also depends in large part on highly variable local conditions, in particular regarding temperature and humidity, of the ground near which the thunderstorms form, such conditions more specifically being conditioned by the nature of the ground, the type of vegetation, or the configuration of the relief, which in turn depends on the presence of buildings. Furthermore, compared with potential storms, stormy phenomena are generally sudden, short-lived, ranging from several tens of minutes to several hours, and affect relatively limited zones, several tens of kilometers. As a result, the detection and location of stormy phenomena thus prove particularly complex.

In light of the significant damage that lightning, or more generally thunderstorms, may cause, various researchers have tried to find methods or processes intended to detect, or even locate, lightning, in order to avoid the potential damage that lightning may cause, or even in some cases, to ultimately preserve the infrastructure and living beings. Such methods for detecting lightning are based on different technologies.

As already mentioned, the flashes can be grouped into two main categories: flashes striking the ground, also described as “lightning surges,” and flashes not striking the ground. Within these two categories, the flashes can be subdivided into other subgroups, for example as a function of the specific path of such flashes and/or the direction of the electric current circulating in the light channels associated with each flash. The most widespread flashes generally do not strike the ground and are commonly called “cloud-to-cloud flashes or intra-cloud flashes.” Such flashes, of lower intensity than the flashes striking the ground, in particular make it possible to reduce the differences in spatial charges in a cloud or between the clouds. The number of said intra-cloud flashes is a marker of the convection of the storm cells, well before the appearance of flashes striking the ground. Over the years, it has appeared crucial to observe intra-cloud flashes for a number of reasons: the abrupt increase in the intra-cloud rhythm, which is a precursor for violent thunderstorm events, has already been subject to studies and is generally called “Lightning Jump.” Indeed, in most thunderstorms that can be described as ordinary, the “cloud-to-cloud flashes” generally outnumber the flashes striking the ground by a factor of about two to ten. However, surprisingly, violent thunderstorms produce much higher intra-cloud flash rates than rates of flashes striking the ground, some thunderstorms producing no flashes striking the ground. Thus, the intra-cloud flashes can provide interesting and important indications relative to the thunderstorms, such as, for instance, their growth and/or intensity rates, consequently leading to significant applications relative to immediate thunderstorm forecasting. In most thunderstorms, one or several intra-cloud flashes precede the first flash striking the ground, while the storm may already have begun to develop and become electrified. Generally, several minutes to several tens of minutes may elapse between the first intra-cloud flash and the first range of flashes striking the ground. This delay may be crucial in some cases, since it makes it possible to use the observations made in connection with the intra-cloud flashes in order to provide warnings or alerts regarding the lightning that may strike the ground, depending on the position of the storm.

The intra-cloud flashes and the flashes striking the ground emit one or several electromagnetic waves, broadly qualified as electromagnetic energy, over a wide range of frequencies. Depending on the type of flashes, the distribution of the emitted electromagnetic energy as a function of the frequency is different. The flashes striking the ground for example have a spectral frequency distribution in the low frequencies, on the order of several kilohertz. The intra-cloud flashes, in turn, have a spectral density in the very high frequencies, or even ultrahigh frequencies. Such disparities in the spectral distribution come from the size of the flashes, more specifically the wavelength. Thus, a flash striking the ground generally has a wavelength on the order of several kilometers, while an intra-cloud flash generally has a wavelength on the order of a meter.

The majority of this energy is contained in the very high frequency (VHF) or ultrahigh frequency (UHF) pulses or “gusts,” such pulses being more or less long and/or sudden. Such electromagnetic emissions can be categorized and processed generally in traditional radio frequency ranges related to common processing bands of the signal. Due to significant differences in the frequencies and the amplitudes of the electromagnetic radiation at such frequencies, several techniques have been developed to detect various processes in the intra-cloud flashes and the flashes striking the ground.

Historically, a first relatively old technique, since it dates back to the end of the 19^{th} century, first consisted of developing a system using a detection device based solely on the magnetic field (also known as Magnetic Direction Finding (MDF)) combined with one or several narrowband radio receivers in the very low and low frequency ranges. The first experiments in particular sought to understand the electromagnetic fields produced by the flashes and were primarily based on detecting vertical flashes, that is to say, flashes striking the ground. Such a first technique in particular demonstrated the importance of calibration before initiating the electric field measurements and the importance of the detection direction. Subsequently, to try to satisfy such constraints, around the 1950s, other researchers used time of arrival (ToA) geolocation techniques (also called Time of Flight (ToF)) for the first time in the geolocation of lightning. Such geolocation techniques of the ToA type use the time difference constant between the arrival of the low-frequency signals and sensors positioned on the ground to calculate the location of meteorological events including flashes striking the ground. However, these techniques also have a certain number of limitations and drawbacks, in particular regarding terrain and in light of conductivity effects on the propagation speed of the lightning signals. Furthermore, each system based on a ToA-type detection identifies a unique and specific function or form of a signal, in order to provide the most precise possible times of arrival, on the order of a hundred nanoseconds. Such a signal function or form must thus be considered common through a certain number of systems that are substantially remote from one another, said systems advantageously being networked. Any signal forms or functions must then be sufficiently separated over time in order to reduce, or even avoid, correlation errors among the systems. Furthermore, such detection systems of the ToA type are highly sensitive in terms of signal-to-noise ratio.

The existence of intra-cloud flashes has thus been known for some time, but the implementation of systems or equipment for detecting and locating electromagnetic waves, more specifically intra-cloud flashes, still remains delicate and complex today. Indeed, in the frequency range where such flashes radiate, more specifically in very high or ultrahigh frequencies, such electromagnetic waves propagate in a substantially direct direction. As a result, the sites or locations selected for the installation or placement of systems for detecting said flashes must be devoid of all obstacles and/or sources emitting electromagnetic fields. Additionally, the support(s) on which said systems are installed also present constraints, since they must satisfy a certain number of specific characteristics, in order in particular to limit or even eliminate masking effects, multiple reflections, phase shifts that may be experienced by the electromagnetic waves one is seeking to detect.

In the storm cells, there are tens of thousands of electromagnetic sources in the form of intra-cloud flashes, unlike the flashes hitting the ground. When such intra-cloud flashes are detected using technologies of the ToA type, a large number of stations must be used in a limited space, then involving relatively long computing times due to a large volume of information to be processed. It is thus impossible to obtain information in real time on the intra-cloud flashes using technologies based on the ToAs.

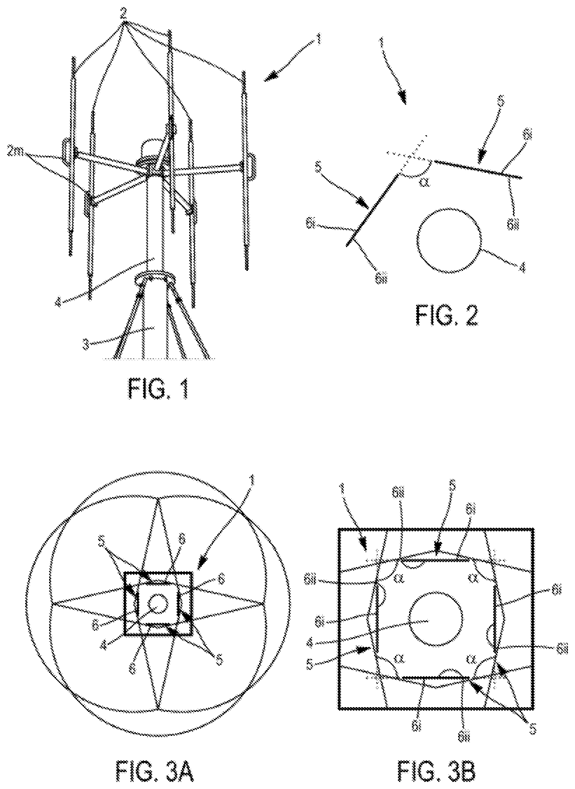

Owing to the developments of new technologies and knowledge, faced with the drawbacks previously mentioned in connection with the technologies previously described, other players have tried to base themselves on alternative techniques to detect lightning by for example using systems based on a detection by interferometry. Interferometry consists of a measuring method using the phase difference of a coherent electromagnetic wave, the phase then being measured by two receivers at two separate points. The use of interferometry proves particularly smart, since detection systems based on interferometry do not require a specific signal form and operate relatively easily on noisy signals. FIG. 1 shows a first exemplary embodiment of a known system for detecting an electromagnetic source by interferometry that is already commercially available. Such a known system 1 for detecting an electromagnetic source, also described as an antenna, aims to capture the lightning completely, whether intra-cloud flashes and/or flashes striking the ground, since it uses not only high-frequency interferometric technologies to detect intra-cloud flashes, but also technologies with magnetic orientation and low-frequency time of arrival to detect flashes striking the ground.

Said detection system 1 consists of an unambiguous array, such a system or array advantageously being arranged to operate at very high frequencies, that is to say, frequency bands of between one hundred eleven (111) and one hundred seventeen (117) megahertz. To ensure the observation or location of intra-cloud flashes, said system 1 comprises at least five conductive elements in the form of five dipoles 2. The system 1 is thus described as unambiguous, that is to say, the distance between the dipoles is less than a half-wavelength, such a distance depending on the coupling terms between the dipoles. Within the meaning of the invention and throughout the document, “dipole,” which can also be described as antenna or dipolar antenna module, refers to any receiving element or object made up of two metal strands, powered in its middle 2m, that is to say, between two such strands, and intended to receive all or part of the electromagnetic energy emitted by a flash, or more generally by lightning. In order to ensure the cohesion of the different dipoles 2 according to a determined arrangement in all directions at three hundred sixty degrees, said detection system 1 includes a central part 4, cooperating with each of the dipoles 2 respectively by means of an advantageously sized dielectric element. The five dipoles 2 of said system 1 are advantageously positioned equidistantly from said central part 4. The latter is further arranged to cooperate with a low-frequency sensor, said sensor using technologies with a magnetic orientation, time of arrival (ToA) and/or low-frequency magnetic goniometry, said sensor being arranged to detect or locate lightning strikes. Such a central part 4 may further be configured to cooperate simultaneously and integrally with a geolocation receiver of the GPS (Global Positioning System) type, thus allowing the synchronization, calibration and benchmarking of other detection systems positioned in other locations of interest and spatially separated. The detection system 1 optionally includes a mast 3 arranged to cooperate integrally, that is to say, according to a suitable mechanical connection, for example of the embedding type, the central part 4 and also the detection elements of the system. Such a mast 3 in particular makes it possible to position the system 1 for detecting an electromagnetic source in different determined locations of interest, in particular the top of infrastructures.

However, such a known system for detecting an electromagnetic source, like that described in connection with FIG. 1, has, like other detection systems previously mentioned, a certain number of drawbacks. First and as previously mentioned, a known system 1 includes at least five conductive elements in the form of five dipoles. Such a system can thus prove slightly redundant, since certain detections can provide identical information, causing identical processing, or even superfluous processing. Furthermore, the specific architecture or arrangement of such a known system for detecting an electromechanical source, like that described in connection with FIG. 1, requires said system to be installed at the peak of the structure or the infrastructure above which it is positioned. Aside from the difficulties that such an installation may pose in terms of time and number of operators to be requisitioned for such an installation, as well as the maintenance difficulties that such a known system for detecting a source may therefore inflict, the specific arrangement of the latter thus causes a restriction on the number of locations or infrastructures on which said system can be installed. Furthermore, as already mentioned, a system for detecting an electromagnetic source in the form of an array is advantageously arranged to operate at very high frequencies, that is to say, in the frequency bands between one hundred eleven (111) and one hundred seventeen (117) megahertz. The use of such a frequency band requires that the detection system be dimensioned accordingly and thus causes the design of a cumbersome and heavy system. Indeed, the system in the form of an antenna array assumes the form of a cylinder, the dimensions of which are substantially on the order of one hundred twenty centimeters in diameter and one hundred twenty centimeters high. Aside from the substantial bulk, the system is thus complex to install and/or maintain and unsuitable for certain installations and/or often existing infrastructures. Furthermore, the arrangement of said system requires that no metal object be positioned around the system within a distance substantially smaller than ten times the wavelength.

The invention thus makes it possible to address all or some of the drawbacks raised by the known solutions.

Among the many advantages provided by a system for detecting an electromagnetic source by interferometry according to the invention, it bears mentioning that the latter:
offers a system that may be positioned on any type of infrastructure, such a system being relatively insensitive to the mechanical variations and to coupling optionally occurring between different antennas of said system, freeing the operator of said system from systematic calibration of the antennas prior to use thereof;
offers a simple and modular detection system, optionally mobile, thus able to be used in many places, such a system having a low sensitivity to any reflections on the ground;
makes it possible to increase the precision of the location and/or detection of flashes, by using one or several frequency bands for a same antenna module of a detection system.

To that end, in particular provided is a system for interferometrically detecting an electromagnetic source. In order to provide the capture or detection of such an electromagnetic source, and more specifically to guarantee the observation of intra-cloud flashes, a system for detecting an electromagnetic source according to the invention includes two physically separate antenna modules, each antenna module comprising two conductive elements, a planar reflector having a first face and a second face, said first faces of the planar reflectors of said antenna modules respectively and integrally cooperating with said second conductive elements of said antenna modules, the two antenna modules being mutually arranged so that the second faces of the planar reflectors thereof form a projecting angle.

Preferably but non-limitingly, the planar reflectors of the antenna modules of a system for interferometrically detecting an electromagnetic source according to the invention can respectively be oriented to be substantially vertical.

According to one advantageous, but non-limiting embodiment of a system for interferometrically detecting an electromagnetic source according to the invention, in order to facilitate the implementation of the latter, the two conductive elements of each antenna module of said system can advantageously be dipoles.

In a variant or additionally, in order to facilitate the manufacture, installation and maintenance of a system for interferometrically detecting an electromagnetic source according to the invention, the two conductive elements of each antenna module of the latter can have quadrilateral conductive surfaces.

Advantageously but non-limitingly, in order to guarantee an optimal operation of a system for interferometrically detecting an electromagnetic source according to the invention, the two conductive elements and the planar reflector of each antenna module of the latter can cooperate using a dielectric element.

In a variant or additionally, to facilitate the manufacture and installation of each antenna module of a system for interferometrically detecting an electromagnetic source according to the invention on various and varied supports, the planar reflector of each antenna module of the latter can be made up of a metallic mesh.

According to one preferred but non-limiting embodiment, to guarantee an optimal precision in detecting an electromagnetic source, a system for interferometrically detecting an electromagnetic source according to the invention may include four physically separate antenna modules, each antenna module comprising two conductive elements, a planar reflector having a first face and a second face, said first faces of the planar reflectors of said antenna modules respectively and integrally cooperating with said two conductive elements of said antenna modules, the four antenna modules being mutually arranged such that the second faces of their planar reflectors form, in pairs, an angle of ninety degrees.

According to one preferred, but non-limiting embodiment of a system for interferometrically detecting an electromagnetic source according to the invention, in order to ensure an optimal detection, and in particular to improve its precision, while for example avoiding untimely undue pollution by other third-party electromagnetic sources, each antenna module of said system can be arranged to detect an electromagnetic source producing an electromagnetic wave whereof the frequency band is selected from the following set of frequency bands: between 111 and 117 megahertz, between 328.6 and 335.4 megahertz or between 1400 and 1427 megahertz.

In order to make it possible to combine an ambiguous and unambiguous array and thus to increase the precision of the measurements and access a three-dimensional location, even a low elevation, each antenna module of a system for interferometrically detecting an electromagnetic source according to the invention can be arranged to concomitantly receive a plurality of frequency bands.

Other features and advantages will appear more clearly upon reading the following description and examining the accompanying figures, in which:

FIG. 1, previously described, illustrates an exemplary embodiment of a known lightning detection system;

FIG. 2 illustrates a schematic view of a first embodiment of a system for interferometrically detecting an electromagnetic source according to the invention;

FIGS. 3A and 3B show two schematic views of a second embodiment of a system for interferometrically detecting an electromagnetic source according to the invention;

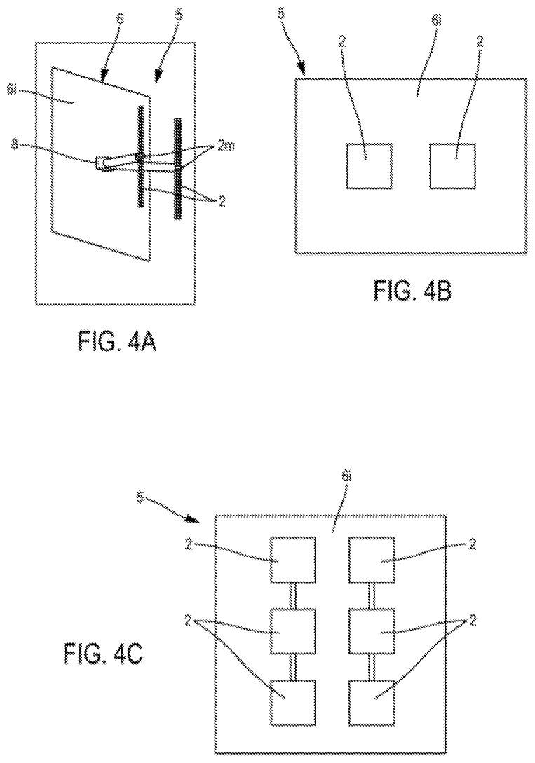

FIGS. 4A, 4B and 4C show respective schematic views of non-limiting exemplary embodiments of antenna modules of a system for interferometrically detecting an electromagnetic source according to the invention.

FIGS. 2, 3A and 3B respectively show first and second embodiments of a system for interferometrically detecting an electromagnetic source according to the invention.

Within the meaning of the invention and throughout the document, “electromagnetic source,” also described as “radio source,” refers to any source, more generally any element, capable of emitting an electromagnetic field, such an electromagnetic field comprising one or several electromagnetic waves. The best-known electromagnetic wave today remains the light wave. Such electromagnetic sources, and more generally such electromagnetic fields, can advantageously be of natural origin, for example those at the origin of flashes or lightning, or created by human activity, for example those at the origin of x-rays used in radiography. The invention will be described through a preferred, but non-limiting exemplary application in which the electromagnetic source consists of lightning or of one or several flashes. For simplification purposes, throughout the document, the expressions “flash” and “lightning” will be used interchangeably to define the electrostatic phenomenon observed by a system according to the invention.

Also within the meaning of the invention, “interferometry” refers to any measuring method making it possible to detect an electromagnetic source and/or field as previously mentioned, using the phase difference of a coherent electromagnetic wave, the phase then being measured by two receivers at two different points, thus making it possible to evaluate the phase shift. The use of interferometry-based systems is particularly clever, since interferometry-based methods have the advantage of working independently of the form of the electromagnetic wave(s) radiated by the lightning or the flashes, increasing the robustness of the systems in light of the deformations that said wave(s) may experience. The precision of the location of an electromagnetic source thus does not depend on the environment and/or the distance separating the system from the flash(es). Furthermore, such interferometry-based systems are particularly effective for a large number of electromagnetic sources to be observed and thus make it possible to obtain information in real time, unlike systems based on ToA techniques. Indeed, ToA technologies require a priori knowledge about the shapes of the electromagnetic waves to be observed and are limited in their use by the distances between the sensors making up a study system, since the time of arrival measurements are limited by the travel time of the distances between sensors in a same system. Depending on the sensors, the order of the electromagnetic waves may optionally be reversed or changed, directly affecting the measurements and therefore the location of the electromagnetic waves.

The principle of interferometry primarily consists of calculating the direction of an electromagnetic source by measuring the phase shift of one or several electromagnetic waves coming from the same source during the propagation, the measurement being done using one or several conductive elements. The equation defining any detection or measurement done and/or performed by a conductive element or dipole of an interferometric system, made up of at least two conductive elements or dipoles, is given by the following formula:

δΦ=2πl/λ sin θ cos φ, where:
ϕ is the elevation, that is to say, the angle between a horizontal plane defined by the ground and the direction of the electromechanical source;
l is the distance between two conductive elements;
λ is the wavelength;
θ is the azimuth, that is to say, the angle in the horizontal plane between the direction of the magnetic source and a reference direction;
φ is the phase shift, that is to say, the difference in phases at a same determined instant between two signals describing the electromagnetic wave for the two conductive elements.
   Such an equation shows a relationship between said phase shift φ of an electromagnetic wave and the azimuth θ and the elevation ϕ, making it possible to locate the electromagnetic source. When two antenna modules, each with two conductive elements, of an interferometric system are combined with two different orientations, a system with two independent equations is then obtained. As a function of the phases or phase shifts measured by the conductive elements of said interferometric system, the resolution of the two-equation system of which then makes it possible to determine the azimuth θ and the elevation ϕ, and ultimately the location of the electromagnetic wave. Therefore, the precision of such a location is a function only of the precision of the phase shift measurement, the precision of such a phase measurement depending only on the signal level relative to the received electromagnetic wave and the integration time, that is to say, the time period during which the receiver must be exposed to the electromagnetic wave or the time period for comparison of the respective phases of the two signals coming from two conductive elements, thus making it possible to reduce or even eliminate the measurement noise, in the case at hand between approximately ten to several hundreds of microseconds.

In the context of the invention, such an interferometry-based system will preferably, but non-limitingly, be used to detect one or several electromagnetic sources, in the case at hand to detect lightning, one or several flashes.

According to a first embodiment described in connection with FIG. 2, a system 1 for interferometrically detecting an electromagnetic source according to the invention includes two antenna modules 5. Within the meaning of the invention and throughout the document, “antenna module” refers to any element, object or device, generally metallic and/or conducting electricity, able to capture or detect one or several electromagnetic waves in space. Such an antenna module is thus considered an element able to be juxtaposed or combined with other elements of the same nature or contributing to a same function, that is to say, to one or several other antenna modules, able to detect one or several electromagnetic waves, making it possible to solve the interferometric equation and locate a flash. All of the antenna modules present within a system for interferometrically detecting an electromagnetic source are advantageously physically separate, that is to say, they do not have a common mechanical link among the different antenna modules. Such an arrangement in the form of separate antenna modules is particularly advantageous, since said antenna modules are then directive and independent of their supports and therefore not subject to any interference caused by their installation sites. As already mentioned, to ensure the detection of an electromagnetic wave of an electromagnetic source by interferometry, at least two antenna modules are necessary to ensure such a detection. Indeed, a system 1 according to the invention, advantageously including two separate antenna modules with two conductive elements, can easily make it possible to locate a flash at a determined moment. A flash being located in three dimensions, it is thus necessary to take two phase shift measurements respectively from two different angles. Nevertheless, when several, at least two, flashes are observable at a same determined instant, it can be necessary to use a greater number of antenna modules within the system. The invention thus cannot be limited to the use of only this number of separate antenna modules within a system 1 to interferometrically detect an electromagnetic source according to the invention. Therefore, the choice of a specific number of conductive elements, or more broadly of antenna modules with respect to another number, will primarily depend on the number of electromagnetic sources that one can or wishes to detect and locate concomitantly using a system 1 to interferometrically detect an electromagnetic source according to the invention. Optionally, the number of antenna modules can also depend on the location of the electromagnetic source(s) to be observed. Thus, an antenna module including N conductive elements will be able locate N−1 sources emitting concomitantly. The antenna modules of a system 1 for detecting an electromagnetic source interferometrically according to the invention are separated, that is to say, there is no physical and/or mechanical cooperation between the different antenna modules 5 making up said system. Such a separation makes it possible to make observations by sector and to simplify the installation of the systems. Indeed, such a system is for example particularly effective in the zones or on the sites where it is not possible for monolithic antenna systems like that described in connection with FIG. 1. According to a first example, on the site of the Aiguille du Midi, the peak is already equipped with telecommunications transmitters and thus cannot receive a monolithic system. A system 1 according to the invention thus makes it possible to install separate antenna modules all around the aerial device and thus to do away with the radiation from the different transmitters existing at this time and existing on the site. According to a second example, said system 1 can be installed around or on any pole, such as a structure of the pylon type.

To ensure the interferometric detection of one or several electromagnetic waves, each antenna module 5 of a system 1 according to the invention comprises two conductive elements 2. Within the meaning of the invention and throughout the document, “conductive element” refers to any object primarily made up of a body, generally but non-limitingly a metal, for example aluminum or copper, the physicochemical characteristics of which allow the passage of an electric current, such an object being intended to receive all or part of the electromagnetic energy emitted by a flash or more generally by lightning or a radiating source. Such conductive elements are advantageously receivers and can thus be described as passive conductive elements. According to one preferred, but non-limiting example, the two conductive elements 2 of an antenna module 5 of a system 1 according to the invention can advantageously be separated by a distance substantially comprised between ten and fifty centimeters, preferably twenty centimeters. Furthermore, said conductive elements are advantageously positioned on a same horizon line. As previously specified, the presence of two conductive elements advantageously makes it possible to measure a phase shift, thus making it possible to determine the azimuth and the elevation of an electromagnetic source producing an electromagnetic wave. Nevertheless, the invention cannot be limited to the number of conductive elements present within each antenna module or the distance separating such conductive elements.

One of the aims of the invention is in particular to propose a system for interferometrically locating an electromagnetic source, including at least two antenna modules, said system then having a directional radiation pattern and thus making it possible to do away with the infrastructure(s) or more generally supports on which such antenna modules are installed and/or to do away with the coupling between the different antenna modules. Indeed, such a coupling between the antenna modules, more specifically the conductive elements, requires a systematic calibration of the detection system, said system being highly sensitive to mechanical variations. Furthermore, the invention also makes it possible to offer a system for interferometrically detecting an electromagnetic source, including at least two antenna modules, said system then having a directional radiation pattern thus making it possible to do away with any ground reflections.

To that end, each antenna module 5 of the system 1 for interferometrically detecting an electromagnetic source according to the invention also comprises a reflector 6. Within the meaning of the invention and throughout the document, “reflector” refers to any apparatus able to reflect one or several electromagnetic waves. In some cases, such a reflector can be responsible for concentrating the received electromagnetic wave(s) toward the conductive elements. According to the invention, such a reflector is preferably, but non-limitingly planar. According to different embodiments of antenna modules described in connection with FIGS. 3A, 3B, 4A to 4C, such a planar reflector 6 advantageously has a first face 6i and a second face 6ii. By definition, such first and second faces 6i and 6ii in particular and advantageously allow the positioning of each separate antenna module within the system according to determined distances, on the order of several centimeters, or even several meters, several tens of meters, in order, as previously mentioned, to do away with the constraints related to the installation of the antenna modules, the coupling of the conductive elements among said antenna modules and/or reflections on the ground of the electromechanical waves.

Furthermore, in addition, according to one preferred, but non-limiting exemplary embodiment (not shown in the figures for simplification purposes) of a system for detecting an electromagnetic source according to the invention, the planar reflector 6 of each antenna module 5 of the latter can be made up of a metal mesh. The use of a planar reflector in the form of a metal mesh is particularly advantageous, since such a reflector is relatively lightweight, inexpensive, and has a minimal wind surface area, said antenna modules generally being installed outside and thus being subject to any meteorological constraints. Preferably but non-limitingly, such a metal mesh can have a grid or mesh with dimensions ten times smaller than the wavelength, in particular to ensure the insulation of the conductive elements. The invention cannot, however, be limited to the use of a specific arrangement, structure and/or composition of a reflector. The choice of a particular arrangement, structure and/or composition of a reflector 6 in light of another arrangement, structure and/or composition may depend, advantageously but non-limitingly, on the electromagnetic source to be located or more broadly on the installation position or location of a system 1 in order to interferometrically detect such an electromagnetic source according to the invention so as in particular to further reduce the manufacturing, installation and/or maintenance costs of such a system 1.

FIGS. 4A, 4B and 4C show respective schematic views of non-limiting exemplary embodiments of antenna modules of a system for interferometrically detecting an electromagnetic source according to the invention.

FIG. 4A shows a first exemplary embodiment of an antenna module 5 of a system 1 for detecting an electromagnetic source according to the invention. According to this advantageous exemplary embodiment, the two conductive elements 2 of each antenna module 5 can respectively consist of dipoles. Within the meaning of the invention and throughout the document, any receiving element or object made up of two metal strands, powered in its middle 2m, that is to say, between two such strands, and designed to receive all or part of the electromagnetic energy emitted by a flash or more generally by lightning. The use of conductive elements in the form of dipoles is particularly clever, since such dipoles are commonly used, therefore inexpensive, and what is more, easy to implement and not very sensitive to the coupling between conductive elements. According to FIG. 4A, such coplanar dipoles can advantageously be substantially trombone-shaped (also referred to as “folded dipole”). Dipoles having such a trombone shape offer a certain number of advantages: first of all, the dipoles, grounded, do not have a build-up of capacitive effect and do not need to be discharged. Furthermore, such dipoles have a better mechanical strength, thus offering a lasting installation over time. According to one preferred, but non-limiting example, when the conductive elements are in the form of dipoles, like the example described in connection with FIG. 4A, and when the working band of the antenna modules of a system 1 according to the invention is on the order of 332 megahertz, the two conductive elements 2 and the reflective plane of an antenna module 5 of a system 1 according to the invention can advantageously be separated by a distance of substantially between ten and fifty centimeters, preferably twenty centimeters.

In a variant, FIG. 4B shows a second exemplary embodiment of an antenna module 5 of a system 1 for detecting an electromagnetic source according to the invention. According to this advantageous exemplary embodiment, the two conductive elements 2 of each antenna module 5 can respectively have quadrilateral conductive surfaces. According to this advantageous embodiment, such an antenna module 5 including two conductive elements 2 having quadrilateral conductive surfaces is comparable to a planar antenna, also described as “patch antenna.” According to this embodiment, the planar reflector can also be conductive. The use of such antenna modules in the form of planar antennas is particularly advantageous, since such antenna modules, due to their very simple design, are very easy to produce industrially. Furthermore, they can be used alone or as elements of an array, in the case at hand a system 1 for interferometrically detecting an electromagnetic source according to the invention. Lastly, said antenna modules in the form of planar antennas have a smaller space requirement in light of other antenna modules, thus allowing easy manipulations and installations, as well as easy integration against an existing structure, such as a building. Such antenna modules in the form of planar antennas, like dipole antennas, have a specific resonance frequency. However, said planar antennas have the advantage of being able to resonate at different frequencies, for example three hundred megahertz and/or one thousand four megahertz. Such antenna modules, described as multi-frequency, make it possible to combine an ambiguous and unambiguous array and thus to increase the precision of the measurements and to access a location in three dimensions, even at low elevation.

The invention cannot, however, be limited to the use of a specific conductive element arrangement or structure for producing an antenna module. The choice of a specific conductive element arrangement or structure in light of another arrangement or structure may advantageously, but non-limitingly, depend on the altitude or the trajectory of the electromagnetic source to be observed and/or located, or more broadly on the installation position or location of a system 1 for interferometrically detecting an electromagnetic source according to the invention so as in particular to further reduce the manufacturing, installation and/or maintenance costs of such a system. Furthermore, as already mentioned, the invention cannot be limited to the number of conductive elements present within each antenna module. According to a third non-limiting exemplary embodiment of an antenna module of a system 1 for interferometrically detecting an electromagnetic source according to the invention described in connection with FIG. 4C, an antenna module of the latter can comprise more than two conductive elements 2, in the case at hand six conductive elements 2. The use of a large number of conductive elements within an antenna module makes it possible to refine the directional lobe of the antenna module and thus to increase the range of such a module.

In order to ensure cohesion of the elements making up the antenna modules of the system 1 for interferometrically detecting an electromagnetic source according to the invention, in the case at hand, for each antenna module, a planar reflector and at least two conductive elements, the first faces 6i of the reflective planes 6 of said antenna modules 5 respectively and integrally cooperate with said two conductive elements 2 of said antenna modules 5. Such a cooperation between the first face 6i of a planar reflector 6 and the two conductive elements 2 can be embodied by any suitable mechanical link, preferably of the embedding type, advantageously permanent or optionally reversible. Such an embedding connection can be done by any suitable fastening means, said first face 6i of a planar reflector 6 and the two conductive elements 2 being mutually arranged to ensure the assembly thereof. As a non-limiting example, when the conductive elements assume the form of dipoles 2, such dipoles can be kept parallel to the reflector 6 using respective rectilinear masts describing a V-shaped association, the base of which cooperates with no degree of freedom with the reflector. The invention cannot, however, be limited to this sole exemplary embodiment. In a variant, according to FIGS. 4B and 4C in particular, the invention provides that the first face 6i of a planar reflector 6 and the two conductive elements 2 of a system 1 for interferometrically detecting an electromagnetic source according to the invention can form or consist of a single and same physical entity.

In a variant or additionally, the invention provides that the two conductive elements 2 and the planar reflector 6, more specifically its first face 6i, of each antenna module 5 of a system 1 for interferometrically detecting an electromagnetic source according to the invention can cooperate using a dielectric element 8. The use of such a dielectric element is particularly advantageous, since such a dielectric element does not conduct electricity and thus makes it possible to insulate the conductive elements from the first face 6i of the reflector, such that they can perform their function fully. In the context of one exemplary embodiment of an antenna module in the form of a planar antenna, as described in particular in connection with FIGS. 4B and 4C, the two conductive elements 2 and the planar reflector 6 of such an antenna module 5 are advantageously and respectively separated by a dielectric blade, said dielectric blade being able to be made primarily from an epoxy resin.

In order to do away with the infrastructure(s), or more generally supports, on which such antenna modules are installed and/or to do away with the coupling between the different antenna modules of a system 1 in order to interferometrically detect an electromagnetic source according to the invention, like that described in connection with FIG. 2, the two antenna modules 5 of the latter are advantageously distanced, that is to say, preferably but non-limitingly separated by several centimeters, or even several meters to several tens of meters, and mutually arranged such that the second faces 6ii of their planar reflectors 6 form a projecting angle α, that is to say, an angle of between zero and hundred eighty degrees. Owing to such a projecting angle, the conductive elements 2 of said system 1 for interferometrically detecting an electromagnetic source are arranged such that they do not interfere with one another, unlike the antenna system described in connection with FIG. 1. According to one preferred, but non-limiting embodiment, the second faces 6ii of the respective planar reflectors 6 of the two antenna modules of a system 1 according to the invention can form an angle α substantially equal to ninety degrees, thus guaranteeing a better resolution and precision to ultimately locate and/or detect one or several electromagnetic sources.

So as also to do away with any ground reflections or infrastructures on which a system 1 for interferometrically detecting an electromagnetic source according to the invention is installed, the planar reflectors 6 of such a system 1 can respectively be oriented to be substantially vertical. Furthermore, in a variant or additionally, still to do away with any reflections on the ground, the planar reflectors 6 of such a system 1 can respectively and also be oriented to be substantially aligned on a same horizon line. Furthermore, the conductive elements of said system 1 for interferometrically detecting an electromagnetic source can also be aligned horizontally, in particular to avoid inherent ground echoes of any reflections of one or several electromagnetic waves on the ground.

According to one preferred, but non-limiting embodiment of a system 1 for interferometrically detecting an electromagnetic source according to the invention described in connection with FIGS. 3A and 3B, the latter can include four antenna modules 5, said antenna modules 5 also in turn being physically and mechanically separated from one another, thus allowing the formation of an exploded system or antenna. Like the first embodiment of a system 1 for interferometrically detecting an electromagnetic source according to the invention described in connection with the figures, each antenna module 5 can comprise two conductive elements 2, able to measure a phase shift. Such conductive elements 2 can also and respectively consist of dipoles or have quadrilateral conductive surfaces. Each antenna module of the detection system further comprises a planar reflector 6 having a first face 6i and a second face 6ii, said first faces 6i of the planar reflectors 6 of said antenna modules 5 respectively and integrally cooperating with said second conductive elements 2 of said antenna modules 5, optionally using a dielectric element. Still according to FIGS. 3A and 3B, the four antenna modules 5 can be mutually arranged such that the second faces 6ii of their planar reflectors 6 form, in pairs, an angle α substantially of ninety degrees. Arranged in this way, the four antenna modules of a system 1 according to the invention can then sweep a coverage area of three hundred sixty degrees. Such a configuration makes it possible not only to do away with the infrastructure(s) or more generally supports on which such antenna modules are installed and/or to do away with the coupling between the different antenna modules, but also to provide the broadest possible coverage area to be able to detect an electromagnetic source, ultimately increasing the sensitivity of the system.

Lastly, the invention provides that each antenna module of the system can be dimensioned so as to be able to use several frequency bands. Preferably but non-limitingly, each antenna module 5 of a system 1 for interferometrically detecting an electromagnetic source according to the invention is arranged to detect an electromagnetic source producing an electromagnetic wave whose frequency band is selected among the following set of frequency bands: between 111 and 117 megahertz, between 328.6 and 335.4 megahertz, or between 1400 and 1427 megahertz. The higher the frequency band used is, the more the space requirement of each antenna module is decreased. Furthermore, the broader the frequency band is, the lower the noise level is. The use of a detection frequency band between 111 and 117 megahertz is particularly advantageous, since the lower the observed spectral band is, the more the electromagnetic wave radiates and the better the signal is. However, such a detection frequency band between 111 and 117 megahertz has the drawback of being close to the transmission and reception bands of FM radios (that is to say, transmitting in frequency modulation), thus limiting the detection ranges. The use of a detection frequency band between 328.6 and 335.4 megahertz or between 1400 and 1427 megahertz is particularly advantageous, since said transmission frequency bands are very restricted, or even prohibited, thus limiting noises or pollution. Furthermore, such frequency bands have worldwide coverage.

As previously mentioned, the antenna modules have a specific resonance frequency. The invention further provides that said antenna modules can be arranged to resonate concomitantly at different frequencies, that is to say, to be able to concomitantly receive several, at least two, frequency bands, for example three hundred megahertz and/or one thousand four megahertz. Such antenna modules, described as multi-frequency, make it possible to combine an ambiguous and unambiguous array and thus to increase the precision of the measurements and access a three-dimensional location, even at low elevation.

According to one specific non-limiting embodiment, with the exception of the coupling between the conductive elements of each antenna module, such an antenna module can be made up of two conductive elements, preferably separated by a distance of about a half-wavelength, each conductive element having dimensions smaller than a half-wavelength. According to different embodiment variants:
for a reception frequency of three hundred megahertz, the wavelength is substantially equal to one meter. The conductive elements of each module are then substantially positioned at fifty centimeters from one another. Due to the existence of a coupling term, the conductive elements of each module are then substantially positioned at fifty centimeters from one another.
for a reception frequency of one thousand five hundred megahertz, the wavelength is substantially equal to twenty centimeters. The conductive elements of each module are then substantially positioned at ten centimeters from one another.
for a reception frequency of one thousand seven hundred megahertz, the wavelength is substantially equal to seventeen centimeters. The conductive elements of each module are then substantially positioned at eight centimeters from one another.

However, the dimensioning and/or the adjustment of each antenna module of a system to interferometrically detect an electromagnetic source according to the invention cannot be limited to the frequency bands selected for such a detection. Such a dimensioning and/or such an adjustment of each antenna module can also depend on the phase excursion, also depending on coupling effects, the radiation pattern of each antenna module, corresponding to a directional lobe and/or any phase undulations, in turn depending on the frequency.

The invention has been described during its use in connection with lightning detection applications, more specifically the detection of intra-cloud flashes. It can also be implemented to act on any other type of flashes, such as lightning surges, or generally any type of electromagnetic waves to be detected and thus to offer a lightning detection system described as total. To that end, a system for detecting an electromagnetic source according to the invention can also include devices for detecting flashes striking the ground, such devices using magnetic orientation and low-frequency time of arrival technologies. The invention cannot be limited to the application within which the system according to the invention is used. According to another embodiment, such a system for interferometrically detecting an electromagnetic source according to the invention could be used in connection with high-voltage lines including one or several sections in which the insulation is defective, thus making it possible to anticipate the maintenance of such high-voltage lines.

Furthermore, a system for detecting an electromagnetic source according to the invention may comprise other accessories, so as in particular, as non-limiting examples, to allow easier maintenance of the antenna modules on different supports or infrastructures or processing means to set, benchmark and/or adjust the measurements. Such accessories can, by way of non-limiting examples, be selected from among one or several preamplifiers, filters, amplifiers and/or digitizers. In a variant or additionally, in order to ensure the coherence of each acquisition line of an antenna module and to guarantee adequate measurements between the antenna modules of a system to detect an electromagnetic source according to the invention, each antenna module can comprise a transmitter positioned between the conductive elements in the reflective plane, in order to benchmark said system regularly.

1. A system for interferometrically detecting an electromagnetic source, comprising: two physically separate antenna modules, each antenna module comprising two conductive elements, a planar reflector having a first face and a second face, said first faces of the planar reflectors of said antenna modules respectively and integrally cooperating with said second conductive elements of said antenna modules, the two antenna modules being mutually arranged so that the second faces of the planar reflectors thereof form a projecting angle.

2. The system according to claim 1, wherein the planar reflectors are respectively oriented to be substantially vertical.

3. The system according to claim 1, wherein the two conductive elements of each antenna module are dipoles.

4. The system according to claim 1, wherein the two conductive elements of each antenna module have quadrilateral conductive surfaces.

5. The system according to claim 1, wherein the two conductive elements and the planar reflector of each antenna module cooperate using a dielectric element.

6. The system according to claim 1, wherein the planar reflector of each antenna module is made up of a metallic mesh.

7. The system according to claim 1, including four physically separate antenna modules, each antenna module comprising two conductive elements, a planar reflector having a first face and a second face, said first faces of the planar reflectors of said antenna modules respectively and integrally cooperating with said two conductive elements of said antenna modules, the four antenna modules being mutually arranged such that the second faces of their planar reflectors form, in pairs, an angle of ninety degrees.

8. The system according to claim 1, wherein each antenna module is arranged to detect an electromagnetic source producing an electromagnetic wave whereof the frequency band is selected from the following set of frequency bands: between 111 and 117 megahertz, between 328.6 and 335.4 megahertz or between 1400 and 1427 megahertz.

9. The system according to claim 1, wherein each antenna module is arranged to concomitantly receive a plurality of frequency bands.
